(19) United States
(12) Patent Application Publication
(10) Pub. No.: US 2015/0279796 A1
(43) Pub. Date: Oct. 1, 2015

(54) QUAD-FLAT NO-LEADS PACKAGE STRUCTURE AND METHOD OF MANUFACTURING THE SAME

(71) Applicant: Lingsen Precision Industries Ltd., Taichung City (TW)

(72) Inventors: Ming-Te TU, Taichung City (TW); Ching-I LIN, Taichung City (TW); Chia-Jen HSU, Taichung City (TW); Sheng-Jen LIN, Taichung City (TW)

(21) Appl. No.: 14/306,905

(22) Filed: Jun. 17, 2014

(30) Foreign Application Priority Data
Mar. 31, 2014 (TW) 103112028

(51) Int. Cl. H01L 23/00; H01L 23/528; H01L 21/768; H01L 21/78; H01L 21/304

(52) U.S. Cl. CPC H01L 24/14; H01L 24/11; H01L 21/78; H01L 21/304; H01L 21/76802; H01L 24/94; H01L 21/768; H01L 23/528; H01L 2224/13025; H01L 2924/401

(57) ABSTRACT

A method of manufacturing a quad-flat no-leads package (QFN) structure includes: forming a conducting layer on a surface of a thin-film layer; forming a plurality of conduction wirings from the conducting layer by a means of circuit layout; electrically connecting contact pads of a die to front ends of the conduction wirings, respectively; forming a plurality of through-holes in the thin-film layer by a means of drilling, such that terminal ends of the conduction wirings are exposed from the through-holes, respectively; and forming a plurality of metal bumps at the through-holes, respectively, such that signals from the die are sent to a bottom surface of the thin-film layer through the conduction wirings. Hence, the QFN structure and the method of manufacturing the same based on application of wafer-level chip-scale package (WLCSP) and extension of tape QFN to simplify the package manufacturing process, cut production costs, and enhance production yield.

### BACKGROUND OF THE INVENTION

1. Technical Field

The present invention relates to package structures and methods of manufacturing the same, and more particularly, to a quad-flat no-leads package structure and a method of manufacturing the same.

2. Description of Related Art

Ever-changing technologies, together with the high-tech electronic sector's frequent release of multifunction personalized electronic products, bring about the rapid advancements of semiconductor packaging in terms of miniaturization, such as a quad-flat no-leads package (QFN) and a wafer-level chip-scale package (WLCSP), to therefore downsize electronic components, cut production costs, and enhance the electrical properties of the electronic components.

To mount a die on the upper surface of a substrate directly, the sector presently processes QFN products by a re-distribution layer (RDL) technique which entails providing a substrate in the form of a copperfoil layer, performing a layout again by the RDL technique, and adhering a wafer to the substrate. However, during the re-distribution step performed with the RDL, the RDL is formed on multiple metal pads within a region, and thus the buildup makes the package larger and renders the manufacturing process more difficult, thereby imposing a negative effect on the production yield and costs.

In conclusion, conventional quad-flat no-leads package (QFN) structures and methods of manufacturing the same have drawbacks and thus there is still room for improvement of the prior art.

### SUMMARY OF THE INVENTION

It is an objective of the present invention to provide a quad-flat no-leads package (QFN) structure and a method of manufacturing the same based on application of wafer-level chip-scale package (WLCSP) and extension of tape quad-flat no-leads package (tape QFN) to simplify the package manufacturing process, cut production costs, and enhance production yield.

In order to achieve the above and other objectives, the present invention provides a method of manufacturing a quad-flat no-leads package (QFN) structure. The method comprises the steps of:

providing a thin-film layer;

providing a conducting layer on a surface of the thin-film layer;

forming a plurality of conduction wirings from the conducting layer by a means of circuit layout;

providing a die having a plurality of contact pads electrically connected to front ends of the conduction wirings, respectively;

forming a plurality of through-holes in the thin-film layer by a means of drilling, such that terminal ends of the conduction wirings are exposed from the through-holes, respectively; and

forming a plurality of metal bumps at the through-holes, respectively, such that signals from the die are sent to the bottom surface of the thin-film layer through the conduction wirings.

The method further comprises the step of forming a glue on the surface of the thin-film layer.

The method further comprises the step of grinding the die.

The through-holes are formed in the thin-film layer by laser drilling.

In order to achieve the above and other objectives, the present invention further provides a method of manufacturing a quad-flat no-leads package (QFN) structure. The method comprises the steps of:

providing a thin-film layer;

providing a conducting layer on an upper surface of the thin-film layer;

forming a plurality of conduction wirings from the conducting layer by a means of circuit layout;

mounting a wafer including a plurality of dice on an upper surface of the conducting layer, wherein the dice are contiguous and each have a plurality of contact pads, and the contact pads are electrically connected to front ends of the conduction wirings, respectively;

forming a plurality of through-holes in the thin-film layer by a means of drilling, such that terminal ends of the conduction wirings are exposed from the through-holes, respectively;

forming a plurality of metal bumps at the through-holes, respectively, such that signals from the dice of the wafer are sent to the bottom surface of the thin-film layer through the conduction wirings; and

cutting along a cutting path between the dice by a means of cutting.

The method further comprises the step of forming a glue on the surface of the thin-film layer.

The method further comprises the step of grinding the dice.

The through-holes are formed in the thin-film layer by laser drilling.

In order to achieve the above and other objectives, the present invention provides a quad-flat no-leads package (QFN) structure which comprises a thin-film layer, a plurality of conduction wirings , a die, and a plurality of metal bumps. The thin-film layer has a plurality of through-holes. The conduction wirings lie on the surface of the thin-film layer. The terminal ends of the conduction wirings are exposed from the through-holes, respectively. The die has a plurality of contact pads electrically connected to the front ends of the conduction wirings, respectively. The metal bumps are disposed at the through-holes, respectively. The metal bumps each have an end connected to a corresponding one of the terminal ends of the conduction wirings and the other end protruding from the bottom surface of the thin-film layer.

A surface of the thin-film layer faces the conduction wirings and has an adhesive glue.

Accordingly, the quad-flat no-leads package (QFN) structure of the present invention is based on application of WLCSP and extension of tape QFN to simplify the package manufacturing process, cut production costs, and enhance production yield.

To help persons skilled in the art gain insight into the constituent elements, features, and objectives of the present invention, the present invention is hereunder illustrated with embodiments and drawings and described in detail so that persons skilled in the art can implement the present invention accordingly. However, the following description is merely illustrative of the implementation of the present invention in terms of technical solution and features. Hence, all simple modifications replacements, and component reduction made to the aforesaid embodiments, without departing from the spirit of the present invention and by persons skilled in the art who have gained insight into the technical solution and features of the present invention, should fall within the scope of the intended protection for the present invention.

### BRIEF DESCRIPTION OF THE SEVERAL VIEWS OF THE DRAWINGS

The technical solution and features of the present invention are hereunder illustrated with preferred embodiments in conjunction with the accompanying drawings, in which:

FIG. 1 is a cross-sectional view of a quad-flat no-leads package (QFN) structure based on application of wafer-level chip-scale package (WLCSP) according to a first preferred embodiment of the present invention;

FIG. 2a through FIG. 2i are schematic views of the process flow of a method of manufacturing a QFN structure based on application of WLCSP according to the first preferred embodiment of the present invention; and

FIG. 3a through FIG. 3g are schematic views of the process flow of a method of manufacturing a QFN structure based on application of WLCSP according to the second preferred embodiment of the present invention.

### DETAILED DESCRIPTION OF THE EMBODIMENT OF THE INVENTION

Objectives, features, and advantages of the present invention are hereunder illustrated with a first preferred embodiment.

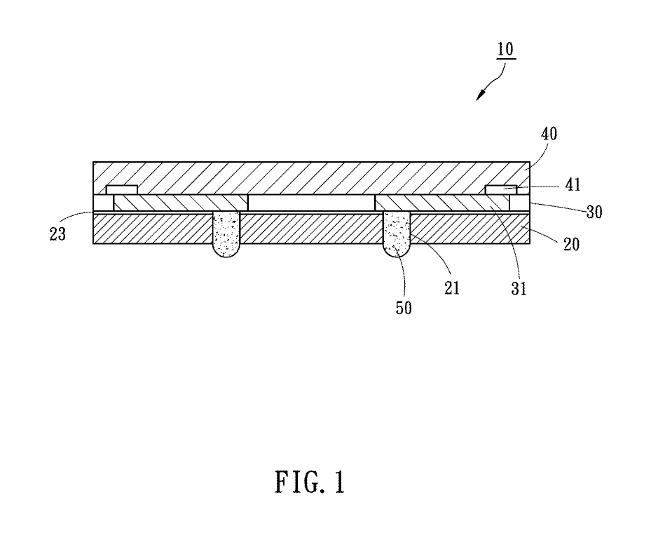

Referring to FIG. 1, in the first preferred embodiment of the present invention, a quad-flat no-leads package (QFN) structure 10 comprises a thin-film layer 20, a plurality of conduction wirings 31, a die 40, and a plurality of metal bumps 50.

The thin-film layer 20 has a plurality of through-holes 21. A surface of the thin-film layer 20 faces the conduction wirings 31 and has an adhesive glue 23.

The conduction wirings 31 lie on the surface of the thin-film layer 20. The terminal ends of the conduction wirings 31 are exposed from the through-holes 21, respectively.

The die 40 has a plurality of contact pads 41. The contact pads 41 are electrically connected to the conduction wirings 31, respectively.

The metal bumps 50 are disposed at the through-holes 21, respectively. The metal bumps 50 each have one end connected to a corresponding one of terminal ends of the conduction wirings 31 and the other end protruding from the bottom surface of the thin-film layer 20.

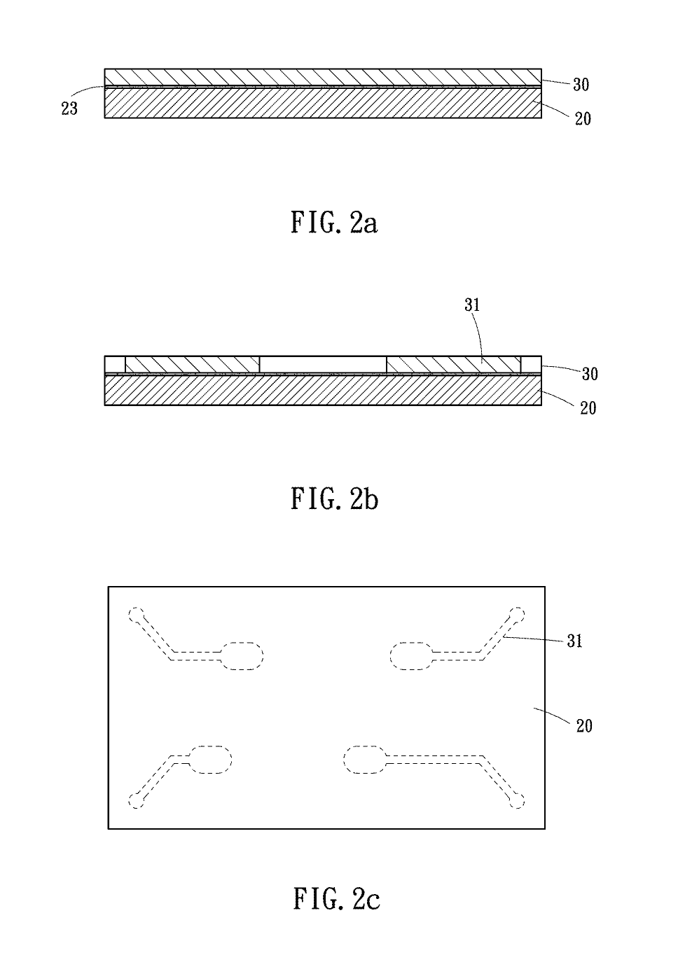

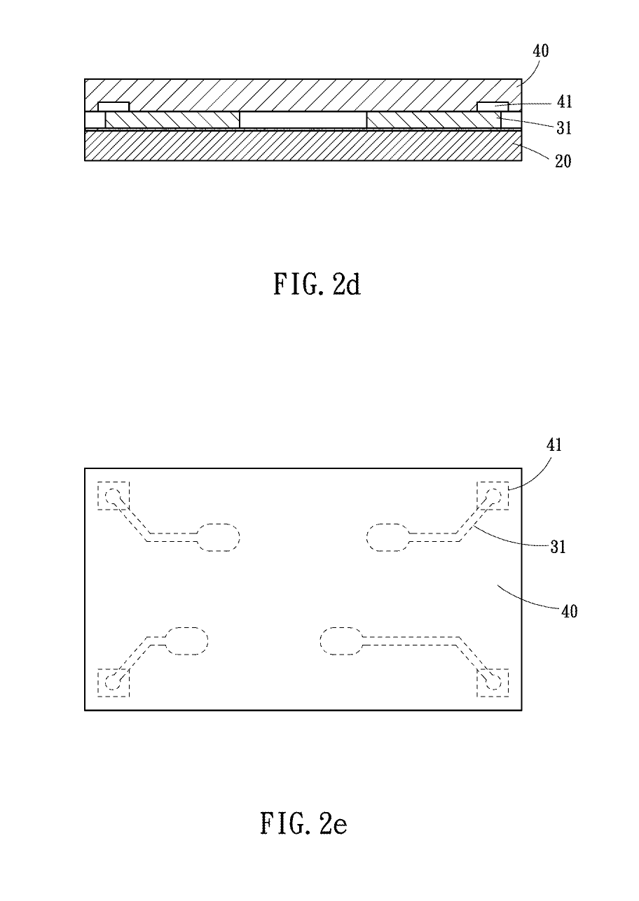

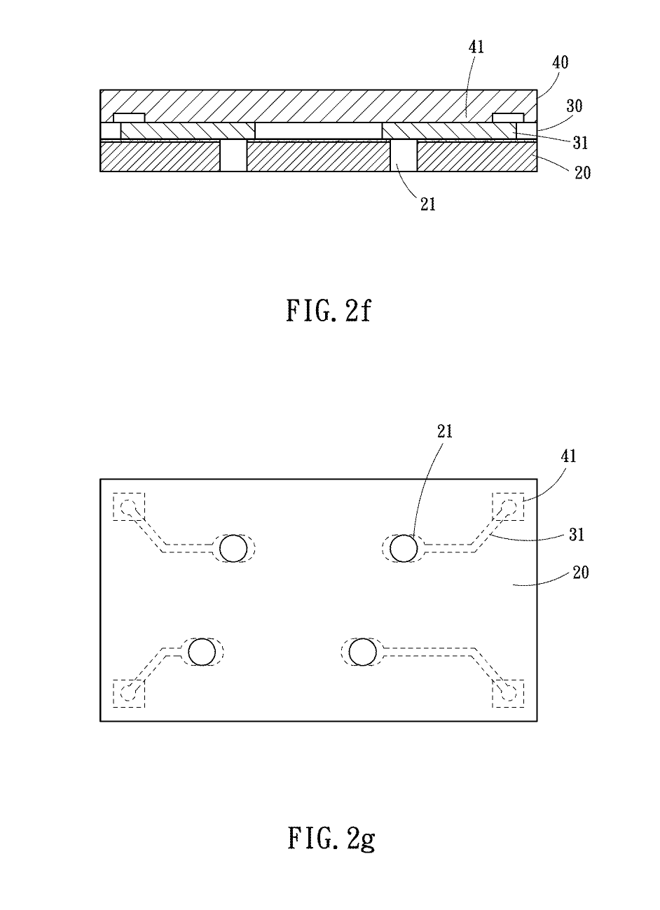

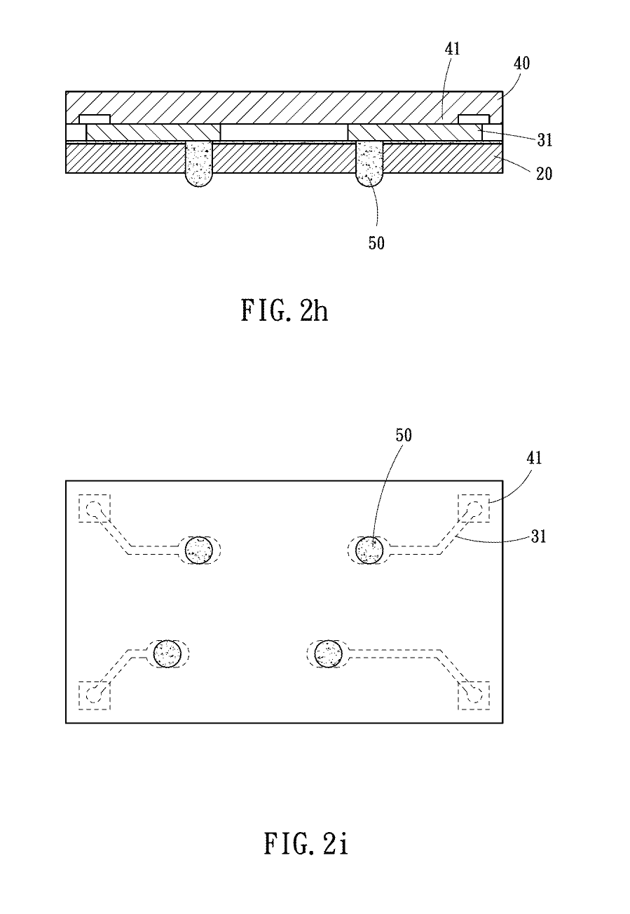

Referring to FIG. 2, there are shown schematic views of the process flow of a method of manufacturing a quad-flat no-leads package structure 10 according to the first preferred embodiment of the present invention. The process flow of the method comprises the steps as follows:

Step A: referring to FIG. 2a, step A involves forming a conducting layer 30 on the upper surface of the thin-film layer 20. In this embodiment, the conducting layer 30 is a copper foil, wherein step A further involves forming a glue 23 on the upper surface of the thin-film layer 20 in advance, such that the thin-film layer 20 assumes the form of an adhesive tape. As the thin-film layer 20 is like an adhesive tape with the glue 23, the conducting layer 30 and the thin-film layer 20 can be easily adhered to each other so as to render the manufacturing process easier.

Step B: referring to FIG. 2b and FIG. 2c, step B involves forming the conduction wirings 31 from the conducting layer 30 by a means of circuit layout. In this embodiment, the means of circuit layout enables the conduction wirings 31 to be formed from the conducting layer 30 by a re-distribution technique, thereby forming a re-distribution Layer (RDL) well-known among persons skilled in the art.

Step C: referring to FIG. 2d and FIG. 2e, step C involves providing a die 40 which has a plurality of contact pads 41. The contact pads 41 are electrically connected to the front ends of the conduction wirings 31, respectively.

Step D: referring to FIG. 2f and FIG. 2g, step D involves forming a plurality of through-holes 21 in the thin-film layer 20 by a means of drilling, such that the terminal ends of the conduction wirings 31 are exposed from the through-holes 21, respectively. The through-holes 21 are formed in the thin-film layer 20 by laser drilling.

Step E: referring to FIG. 2h and FIG. 2i, step E involves forming a plurality of metal bumps 50 at the through-holes 21, respectively, such that signals from the die 40 are sent to the bottom surface of the thin-film layer 20 through the conduction wirings 31 and sent out from the metal bumps 50. The metal bumps 50 are formed at the through-holes 21, respectively, by ball mounting to enhance production quality and efficiency.

The process flow of the method further comprises, between step C and step D, the step of grinding the die 40, such that the die 40 thus ground is of a predetermined thickness.

To describe the structure, features, and advantages of the present invention, the present invention is hereunder illustrated with a second preferred embodiment and drawings. A portion of the technical features of the present invention is described before and thus is not described again for the sake of brevity.

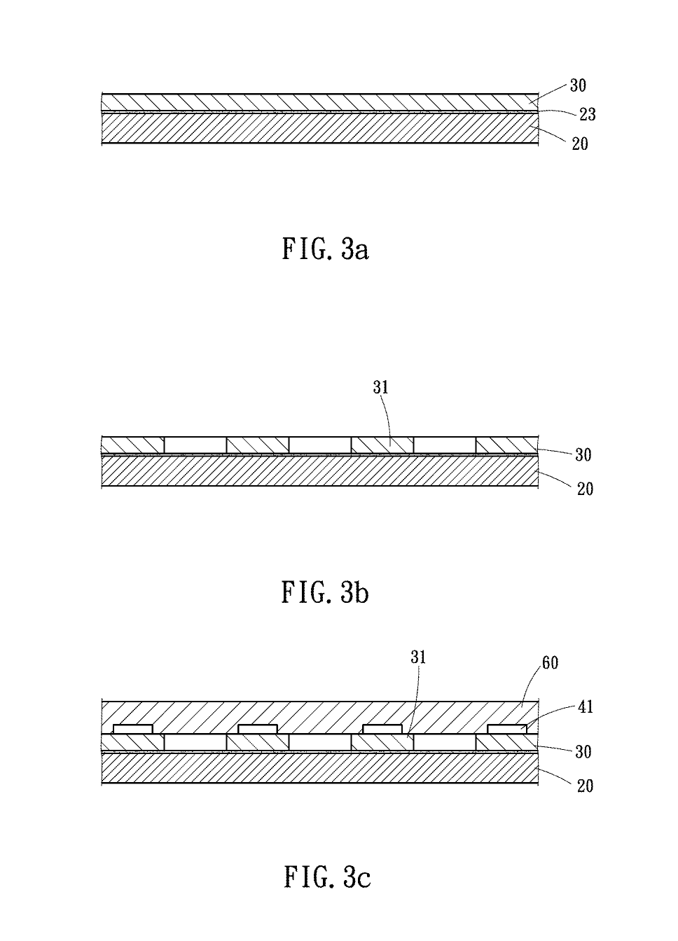

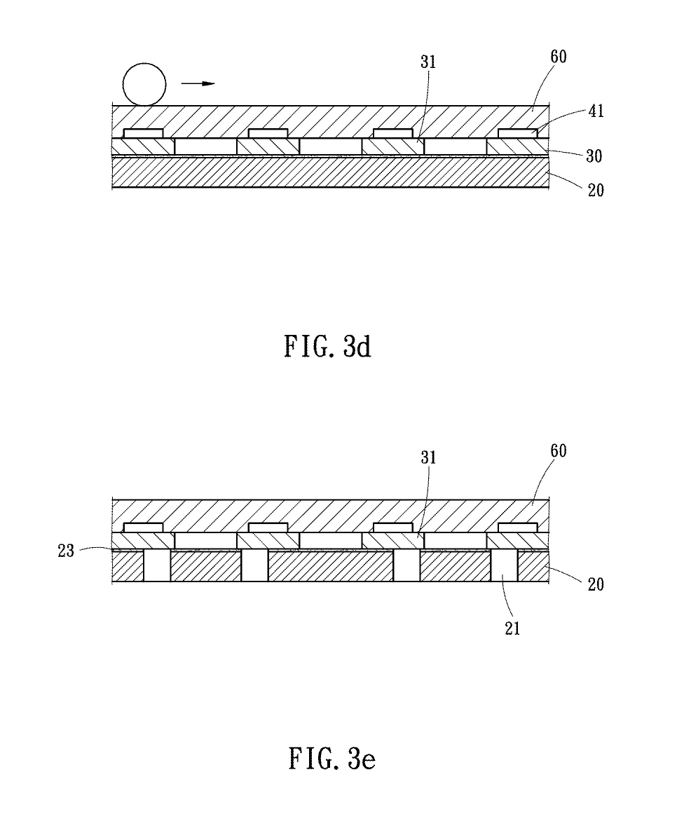

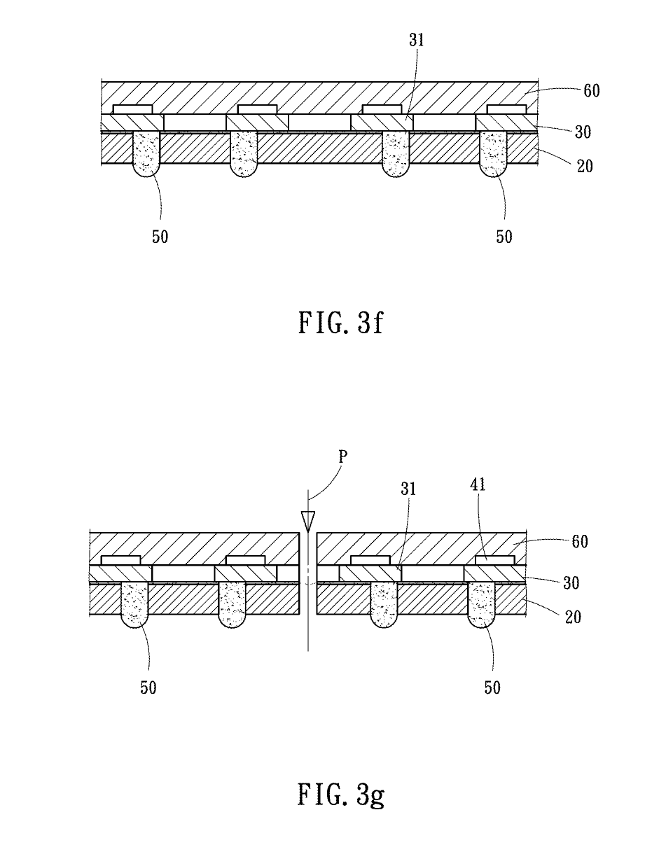

Referring to FIG. 3, there are shown schematic views of the process flow of a method of manufacturing a quad-flat no-leads package structure 10′ according to the second preferred embodiment of the present invention. The process flow of the method comprises the steps as follows:

Step A: referring to FIG. 3a, step A involves forming the conducting layer 30 on the upper surface of the thin-film layer 20. In practice, the surface of the thin-film layer 20 has the glue 23, and the glue 23 enables the conducting layer 30 to be easily adhered to the thin-film layer 20.

Step B: referring to FIG. 3b, step B involves forming the conduction wirings 31 from the conducting layer 30 by a means of circuit layout.

Step C: referring to FIG. 3c, step C involves mounting a wafer 4 including the dice 40 on the upper surface of the conducting layer 30. The dice 40 are contiguous and each have the contact pads 41. The contact pads 41 are electrically connected to front ends of the conduction wirings 31, respectively.

Step D: referring to FIG. 3d, step D involves performing a grinding process on the upper surface of the wafer 4, such that the wafer 4 thus ground is of a predetermined thickness.

Step E: referring to FIG. 3e, step E involves forming a plurality of through-holes 21 in the thin-film layer 20 by a means of drilling, such that terminal ends of the conduction wirings 31 are exposed from the through-holes 21, respectively. The through-holes 21 are formed in the thin-film layer 20 by laser drilling.

Step F: referring to FIG. 3f, step F involves forming a plurality of metal bumps 50 at the through-holes 21, respectively, such that signals from the dice 40 of the wafer 4 are sent to the bottom surface of the thin-film layer 20 through the conduction wirings 31.

Step G: referring to FIG. 3g, step G involves cutting along the cutting path P between the dice 40 by a means of cutting. Upon completion of the cutting, the quad-flat no-leads package structure 10′ according to the second preferred embodiment of the present invention is obtained.

In conclusion, according to the present invention, the quad-flat no-leads package structures 10, 10′ and a method of manufacturing the same are based on application of wafer-level chip-scale package (WLCSP) and extension of tape quad-flat no-leads package (tape QFN) to simplify the package manufacturing process, cut production costs, and enhance production yield.

Constituent elements disclosed in the above embodiments of the present invention are illustrative rather than restrictive of the scope of the present invention. Hence, all variations and replacements of equivalent components should fall within the claims of the present invention.

What is claimed is:

1. A method of manufacturing a quad-flat no-leads package (QFN) structure, the method comprising the steps of:
providing a thin-film layer;
providing a conducting layer on a surface of the thin-film layer;
forming a plurality of conduction wirings from the conducting layer by a means of circuit layout;
providing a die having a plurality of contact pads electrically connected to front ends of the conduction wirings, respectively;
forming a plurality of through-holes in the thin-film layer by a means of drilling, such that terminal ends of the conduction wirings are exposed from the through-holes, respectively; and
forming a plurality of metal bumps at the through-holes, respectively, such that signals from the die are sent to a bottom surface of the thin-film layer through the conduction wirings.

2. The method of claim 1, further comprising the step of forming a glue on the surface of the thin-film layer.

3. The method of claim 1, further comprising the step of grinding the die.

4. The method of claim 1, wherein the through-holes are formed in the thin-film layer by laser drilling.

5. A method of manufacturing a quad-flat no-leads package (QFN) structure, the method comprising the steps of:
providing a thin-film layer;
providing a conducting layer on an upper surface of the thin-film layer;
forming a plurality of conduction wirings from the conducting layer by a means of circuit layout;
mounting a wafer including a plurality of dice on the upper surface of the conducting layer, wherein the dice are contiguous and each have a plurality of contact pads, and the contact pads are electrically connected to front ends of the conduction wirings, respectively;
forming a plurality of through-holes in the thin-film layer by a means of drilling, such that terminal ends of the conduction wirings are exposed from the through-holes, respectively;
forming a plurality of metal bumps at the through-holes, respectively, such that signals from the dice of the wafer are sent to a bottom surface of the thin-film layer through the conduction wirings; and
cutting along a cutting path between the dice by a means of cutting.

6. The method of claim 5, further comprising the step of forming a glue on the upper surface of the thin-film layer.

7. The method of claim 5, further comprising the step of grinding the dice.

8. The method of claim 5, wherein the through-holes are formed in the thin-film layer by laser drilling.

9. A quad-flat no-leads package (QFN) structure, comprising:
a thin-film layer having a plurality of through-holes;
a plurality of conduction wirings lying on a surface of the thin-film layer and having terminal ends exposed from the through-holes, respectively;
a die having a plurality of contact pads electrically connected to front ends of the conduction wirings, respectively; and
a plurality of metal bumps disposed at the through-holes, respectively, wherein the metal bumps each have an end connected to a corresponding one of the terminal ends of the conduction wirings and another end protruding from a bottom surface of the thin-film layer.

10. The quad-flat no-leads package (QFN) structure of claim 9, wherein a surface of the thin-film layer faces the conduction wirings and has an adhesive glue.
